(19) United States
(12) Patent Application Publication
(10) Pub. No.: US 2025/0226262 A1
(43) Pub. Date: Jul. 10, 2025

(54) FEEDTHROUGH VIA WITH REDUCED RESISTANCE FOR DIRECT CONNECTION TO BACKSIDE METALS

(71) Applicant: Taiwan Semiconductor Manufacturing Company, Ltd., Hsin-Chu (TW)

(72) Inventors: I-Wen Wu, Hsinchu City (TW); Chen-Ming Lee, Taoyuan County (TW); Fu-Kai Yang, Hsinchu City (TW); Mei-Yun Wang, Hsin-Chu (TW)

(21) Appl. No.: 18/407,800

(22) Filed: Jan. 9, 2024

(51) Int. Cl. H01L 21/768; H01L 21/8234; H01L 29/66; H01L 29/78

(52) U.S. Cl. CPC H01L 21/76879; H10D 30/024; H10D 30/797; H10D 84/0151; H10D 84/0158; H10D 84/038

(57) ABSTRACT

One aspect of the present disclosure pertains to a semiconductor structure. The semiconductor structure includes a first circuit area having: an active region extending lengthwise along a first direction, the active region includes a channel region between source/drain (S/D) features and a gate over the channel region, a dielectric structure over and surrounding the active region, a metal contact penetrating through a top surface of the dielectric structure to land on one of the S/D features, and a first via landing on the metal contact. The semiconductor structure includes a second circuit area having: the dielectric structure, a feedthrough via penetrating through the top surface of the dielectric structure and a bottom surface of the dielectric structure, and a second via landing on the feedthrough via. The first via and the second via have substantially coplanar bottom surfaces.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

One advancement is in the use of feedthrough vias to connect signals from the frontside of the wafer to the backside of the wafer. This allows for flexibility in forming semiconductor features on both front and backsides of a semiconductor structure. In one example, frontside source/drain features may connect to backside power rails through a feedthrough via. However, forming feedthrough vias are often costly due to the space they take up. For example, the feedthrough vias may be formed in large, dedicated feedthrough cell areas isolated from transistor circuit areas. These dedicated feedthrough cell areas take up additional space in the circuit layout. To avoid area penalty, better integration between the feedthrough vias and the transistor region areas is needed. For example, the feedthrough cell areas may be formed directly between and surrounded by transistor regions.

However, when surrounded by transistor circuit areas, there are challenges in forming feedthrough vias such as avoiding coupling with nearby transistor contact features, overlay issues when forming the feedthrough vias from a back side, and with reaching low resistance in a limited area. Therefore, although existing methods of forming feedthrough vias have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIG. 1A illustrates a top view of a semiconductor structure having a feedthrough circuit area surrounded by transistor circuit areas, according to an embodiment of the present disclosure.

FIGS. 1B-1D illustrate cross-sectional views of an embodiment semiconductor structure cut along the lines B-B′, C-C′, and D-D′ in FIG. 1A, according to an embodiment of the present disclosure.

FIG. 2A illustrates a top view of a semiconductor structure having a feedthrough circuit area surrounded by transistor circuit areas, according to another embodiment of the present disclosure.

FIGS. 2B-2C illustrate cross-sectional views of an embodiment semiconductor structure cut along the lines B-B′ and C-C′ in FIG. 2A, according to an embodiment of the present disclosure.

FIG. 3 illustrates a flow chart of a method to form a semiconductor structure having a feedthrough via adjacent to device level metal contacts, according to an embodiment of the present disclosure.

FIGS. 4, 5, 6, 7, 8A, 8B, 9A, and 9B the formation of a semiconductor structure at intermediate stages of fabrication, processed in accordance with the method of FIG. 3, according to an embodiment of the present disclosure.

FIG. 10 illustrates a flow chart of a method to form a semiconductor structure having a feedthrough via adjacent to device level metal contacts, according to another embodiment of the present disclosure.

FIGS. 11, 12, 13, 14, 15, 16A, 16B, 17A, and 17B illustrate the formation of a semiconductor structure at intermediate stages of fabrication, processed in accordance with the method of FIG. 10, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to semiconductor structures having a feedthrough circuit area surrounded by transistor circuit areas. The feedthrough circuit area includes a feedthrough via that continuously and uniformly spans from a via rail on a frontside of a wafer to a backside metal on a backside of the wafer. The feedthrough via may be laterally adjacent to and surrounded by source/drain contacts disposed over source/drain features in the transistor circuit areas. The feedthrough via penetrates deeper than the source/drain contacts to contact the backside metal on the backside of the wafer. The feedthrough via provides direct connection from the frontside via rail to the backside metal, and there are no other intermediary metal contacts or vias between the frontside via rail and the backside metal. As such, the resistance of the feedthrough metal connection is reduced by eliminating any glue layer interfaces between metal features. The feedthrough via is formed from the backside of the wafer and may partially penetrate a backside surface of the frontside via rail to breakthrough the glue layer of the frontside via rail, thereby further reducing feedthrough resistance. Due to the feedthrough via not being limited by patterning dimensions of nearby source/drain contacts, the feedthrough via may also be formed wider than the source/drain contacts, thereby even further reducing feedthrough resistance. Since the feedthrough via is formed from the backside, the top surface of the feedthrough via may be narrower than the bottom surface of the feedthrough via. To improve landing and overlay, the feedthrough via may be formed as part of a self-aligned process.

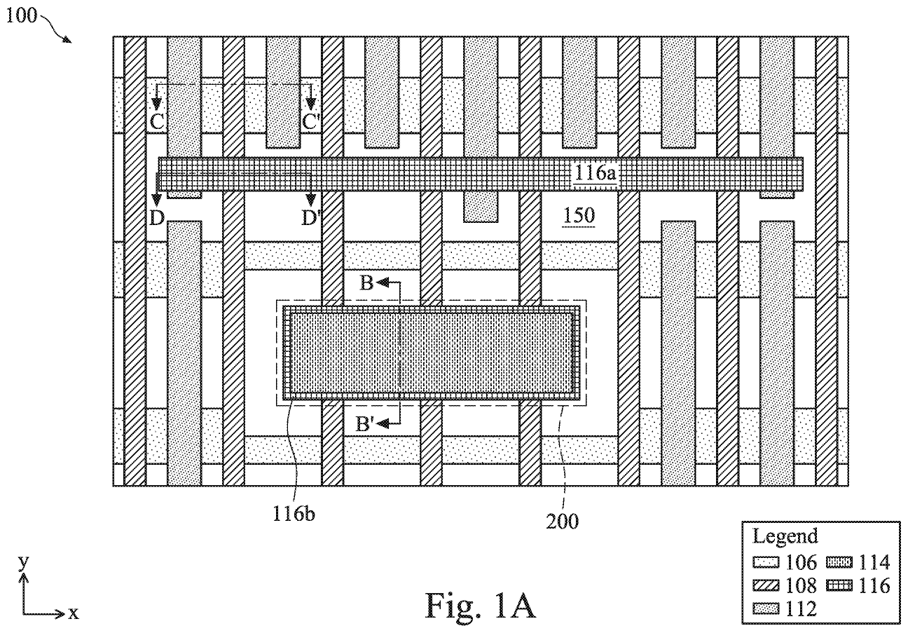

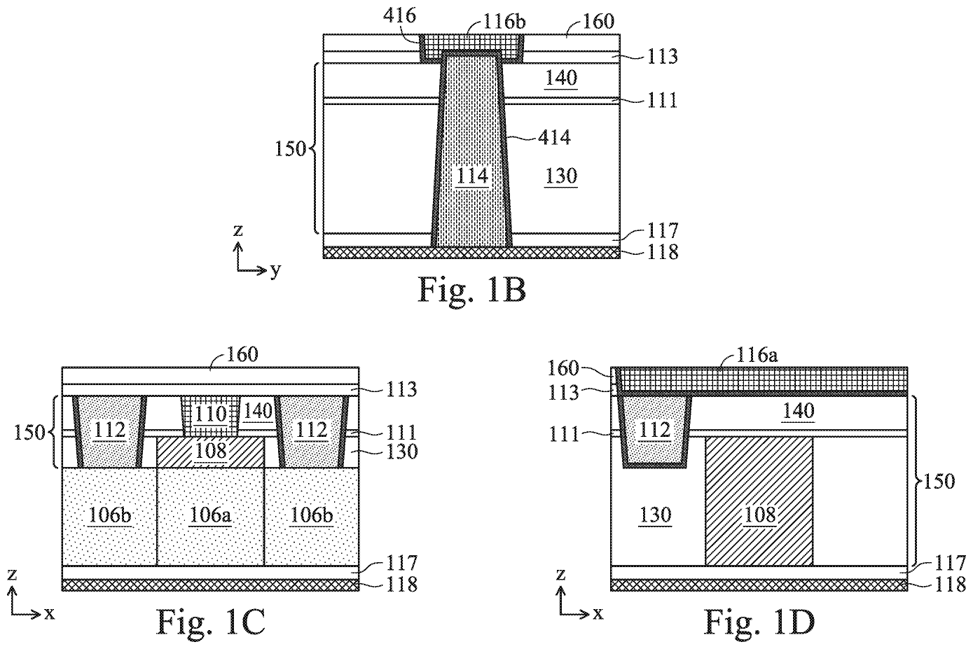

FIG. 1A illustrates a top view of a semiconductor structure 100 having a feedthrough circuit area 200 surrounded by transistor circuit areas. The transistor circuit areas include active regions 106 extending lengthwise along the x direction. The active regions 106 include channel regions (regions under metal gate structures 108) and source/drain (S/D) regions adjacent to the channel regions. The active regions 106 may be fin active regions protruding from a substrate (not shown). Each of the channel regions may include a stack of semiconductor channels for gate-all-around semiconductor devices. Alternatively, each of the channel regions may include single fin-shaped channels for fin semiconductor devices. The S/D regions adjacent the channel regions include epitaxial S/D features.

Still referring to FIG. 1A, the semiconductor structure 100 (or transistor circuit areas thereof) includes metal gate structures 108 extending lengthwise along the y direction and disposed over the channel regions of the active regions 106. For gate-all-around semiconductor devices, each of the metal gate structures 108 wraps around a stack of semiconductor channels in the channel regions. For fin semiconductor devices, each of the metal gate structures 108 wraps around top and side portions of fin-shaped channels protruding from the substrate. Each metal gate structure 108 may include a gate electrode over a gate dielectric, and the gate dielectric is disposed on the channel region of the active regions 106. In some embodiments, an interfacial layer (e.g., a silicon oxide layer) is disposed vertically between the channel region and the gate dielectric. The gate dielectric layer includes a high-k dielectric material, such as materials having a dielectric constant greater than silicon oxide (k≈3.9). The gate dielectric layer may include HfO, LaO, ZrO, AlO, TiO, or TaO. The gate electrode includes a suitable conductive material, such as Al, W, Co, TiAl, TiN, or other metal gate materials.

Still referring to FIG. 1A, the semiconductor structure 100 (or transistor circuit areas thereof) includes S/D contacts 112 formed over the epitaxial S/D features of the active regions 106. As shown, the S/D contacts 112 may be slot S/D contacts that extend lengthwise along the y direction. The S/D contacts 112 land on S/D features of the active regions 106. In some embodiments, like the one shown, a single S/D contact 112 may land on multiple S/D features in multiple active regions 106. The S/D contacts 112 are device-level contacts. In an embodiment, to facilitate better metal fill for device-level contacts (avoid air gaps and voids), the S/D contacts 112 include metal materials with good gap-fill characteristics such as Al, W, Co, TiAl, TIN, or Ru, (as opposed to copper).

Still referring to FIG. 1A, the semiconductor structure 100 includes a dielectric structure 150 disposed over and surrounding the active region 106 and the metal gate structures 108. The dielectric structure 150 includes one or more interlayer dielectric (ILD) layers and has a top surface substantially coplanar with top surfaces of the S/D contacts 112. The dielectric structure 150 extends and is present throughout the transistor circuit areas and the feedthrough circuit area 200.

Still referring to FIG. 1A, the semiconductor structure 100 includes a feedthrough circuit area 200. The feedthrough circuit area 200 includes a feedthrough via 114 completely penetrating through the dielectric structure 150 to form a metal interconnect between a frontside of the semiconductor structure 100 and a backside of the semiconductor structure 100. In the embodiment shown in FIG. 1A, the feedthrough via 114 may be disposed between active regions 106 along the y direction and between S/D contacts 112 along the x direction. The feedthrough via 114 is a device level interconnect and may include similar metal materials as the S/D contacts 112 for good gap-fill characteristics.

Still referring to FIG. 1A, the semiconductor structure 100 includes frontside vias 116 disposed on a top surface of the dielectric structure 150. The frontside vias 116 may land on metal features below, such as S/D contacts 112 or a feedthrough via 114. As shown, the frontside vias 116 may include S/D via rails 116a that extend lengthwise along the x direction to land on multiple S/D contacts 112. For example, the S/D contacts 112 may include source contacts that extend longer (or shorter) in the y direction from the drain contacts. And an S/D via rail 116a lands on the extended portion and connect multiple source (or drain) contacts together. The frontside vias 116 may further include a feedthrough via (FTV) via rail 116b in the feedthrough circuit area 200. The FTV via rail 116b extends lengthwise along the x and y direction over and surrounding the feedthrough via 114. The FTV via rail 116b is disposed on a top surface of the feedthrough via 114.

The frontside vias 116 are interconnects that connect to first metal lines of a metal interconnect structure (not shown) over the frontside vias 116. The frontside vias 116 may be considered device-level interconnects and include similar metal materials as the S/D contacts 112 for good gap-fill characteristics. The metal interconnect structure includes additional stacked metal lines vertically connected by additional interconnect vias for signal routing. The metal features in the metal interconnect structure may have larger dimensions and bulk area as compared to device-level contacts, and thus these metal features can use different metals or metal alloys or a combination thereof, such as poorer gap-fill metal materials without sacrificing conductivity. For example, these upper-level metal features may include materials such as copper, aluminum, tin, silver, or alloy while still achieving better resistivity and saving cost. In other embodiments, these metal features still include similar metal materials as the S/D contacts 112. Note that the device-level features described herein may refer to the active regions 106, metal gate structures 108, S/D contacts 112, feedthrough via 114, and frontside vias 116. The metal interconnect structure described herein may refer to middle interconnect features over the device-level features. Note that in some embodiments, the frontside vias 116 may be considered part of the metal interconnect structure. As such, the frontside vias 116 may include different metal materials as the device-level metal features. For example, the S/D contacts 112 and the feedthrough via 114 include tungsten, and the frontside vias 116 includes copper.

Still referring to FIG. 1A, the feedthrough circuit area 200 may span lengthwise across multiple spacings between metal gate structures 108 along the x direction. The feedthrough circuit area 200 may span widthwise between active regions 106 along the y direction. In the embodiment shown, to reduce unwanted electrical coupling between the feedthrough circuit area 200 and the surrounding transistor circuit areas, portions of the active regions 106 that sandwich the feedthrough circuit area 200 have recessed width in the y direction (e.g., the width is halved).

FIGS. 1B-1D illustrate cross-sectional views of an embodiment semiconductor structure 100 cut along the lines B-B′, C-C′, and D-D′ in FIG. 1A. Although FIGS. 1B-1D may show different features at different cross-sectional views, they show a same vertical thickness portion of the semiconductor structure 100. As such, the height level of various layers across FIGS. 1B-1D are consistent, and the height level of the various features in the semiconductor structure 100 can be compared to each other across FIGS. 1B-1D.

FIG. 1B illustrates a cross-sectional view of the feedthrough circuit area 200 along the y direction. FIG. 1B shows a feedthrough via 114 penetrating through a dielectric structure 150. In the present embodiment, the dielectric structure 150 includes a first interlayer dielectric (ILD) layer 130, an etch stop layer 111 over the first ILD layer 130, and a second ILD layer 140 over the etch stop layer 111. As shown, the feedthrough via 114 completely penetrates through the dielectric structure 150 (including the first ILD layer 130, etch stop layer 111, and second ILD layer 140). In the embodiment shown, the feedthrough via 114 further penetrates through a backside hard mask layer 117 under a bottom surface of the first ILD layer 130. A bottom surface of the feedthrough via 114 lands on a backside metal 118. The backside metal 118 may be part of a backside metal interconnect structure (not shown), which includes additional stacked backside metal lines vertically connected by additional interconnect vias for backside signal routing. The metal features in the backside metal interconnect structure may have similar materials as the metal features in the frontside metal interconnect structure over the frontside vias 116 described above. A top surface of the feedthrough via 114 directly contacts a frontside via 116, such as a FTV via rail 116b as shown. In the embodiment shown, the feedthrough via 114 partially penetrates a bottom surface of the FTV via rail 116b. In other embodiments, the feedthrough via 114 does not penetrate the FTV via rail 116b and lands on a bottommost surface of the FTV via rail 116b. The FTV via rail 116b is embedded in dielectric layers such as an etch stop layer 113 and a third ILD layer 160 over the etch stop layer 113. The FTV via rail 116b may extend wider than the feedthrough via 114 along the x and y direction to allow enough landing space for the feedthrough via 114.

The etch stop layers 111, 113, and hard mask layer 117 may include different dielectric materials from the first, second, and third ILD layers 130, 140, and 160 for etchant selectivity. For example, the etch stop layers 111, 113, and hard mask layer 117 include a nitride-based dielectric such as silicon nitride, silicon oxynitride, silicon carbonitride, silicon carbon oxynitride, or combinations thereof. And the first, second, and third ILD layers 130, 140, and 160 include silicon oxide or an oxide-based dielectric formed with tetraethylorthosilicate, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof.

Still referring to FIG. 1B, the feedthrough via 114 may include a glue layer 414 on its outer surfaces and a fill metal surrounded by the glue layer 414. And the FTV via rail 116b may include a glue layer 416 on its outer surfaces and a fill metal surrounded by the glue layer 416. The glue layers 414 and 416 are seed layers that provide better adhesion and surface contact. They also act as conductive barrier layers to prevent unwanted diffusion or oxidation between the fill metal and surrounding features. However, the glue layers 414 and 416 have higher resistivity than the fill metal (e.g., between 2 to 100 times resistivity). As such, the present disclosure contemplates forming the feedthrough via 114 such that it penetrates a portion of the glue layer 416 surrounding the fill metal of the FTV via rail 116b. As shown, the feedthrough via 114 completely penetrates through a bottom portion of the glue layer 416 and may partially penetrate a portion of the fill metal of the FTV via rail 116b. In this way, overall interconnect resistance is reduced by breaking through a horizontal glue layer interface between the feedthrough via 114 and the FTV via rail 116b. The glue layers 414 and 416 may include titanium, titanium nitride, titanium tungsten, titanium aluminide, titanium carbonitride, titanium aluminum nitride, or combinations thereof. The fill metals may include Al, W, Co, Ru, or combinations thereof. In an embodiment, the glue layers 414 and 416 include titanium nitride, and the fill metals for the feedthrough via 114 and the FTV via rail 116b are both tungsten. In another embodiment, the fill metal for the feedthrough via 114 and the FTV via rail 116b are different (e.g., tungsten for feedthrough via 114 and copper for FTV via rail 116b).

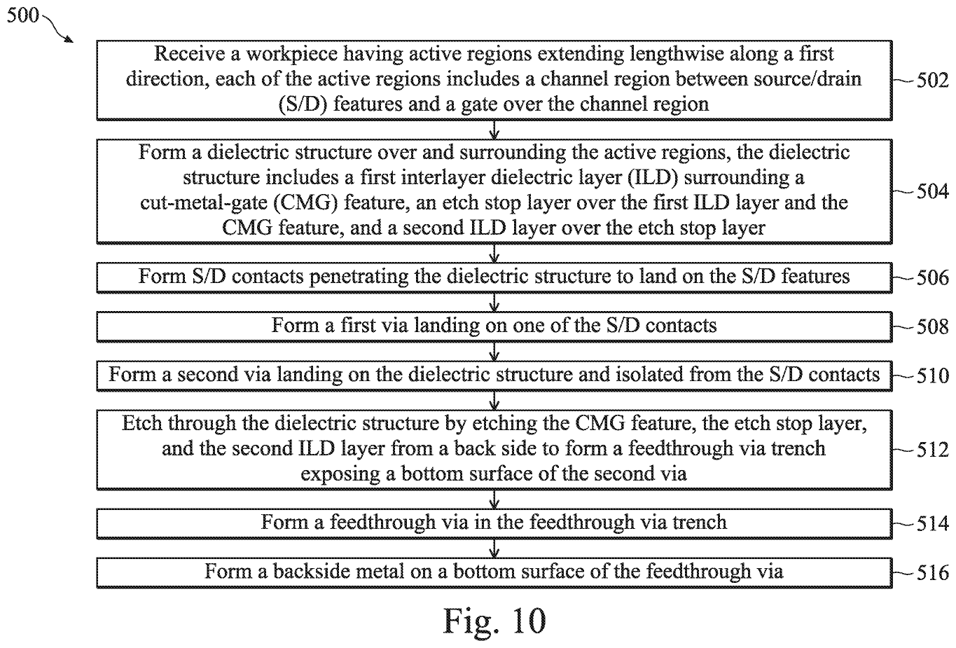

Still referring to FIG. 1B, the feedthrough via 114 continuously and uniformly spans between the backside metal 118 and the FTV via rail 116b. The feedthrough via 114 provides direct connection from the frontside via rail 116b to the backside metal 118, and there are no other intermediary metal contacts or vias between the frontside via rail 116b and the backside metal 118. The FTV via rail 116b directly lands on and contacts a top surface of the feedthrough via 114. And the feedthrough via 114 directly lands on and contacts a top surface of the backside metal 118. As described in more detail below, the FTV via rail 116b is formed from a frontside of the semiconductor structure 100, then the feedthrough via 114 is formed from a backside of the semiconductor structure 100 to land on (or partial penetrate through) a bottom surface of the FTV via rail 116b. Since the FTV via rail 116b is formed from the frontside, the FTV via rail 116b has a narrowing profile from the top surface of the FTV via rail 116b to the bottom surface of the FTV via rail 116b. In other words, along the y direction, the FTV via rail 116b has a wider top surface than a bottom surface. Since the feedthrough via 114 is formed from the backside, the feedthrough via 114 has a narrowing profile from the bottom surface of the feedthrough via 114 to the top surface of the feedthrough via 114. In other words, along the y direction, the feedthrough via 114 has a wider bottom surface than the top surface. As such, the narrower portions of the feedthrough via 114 and FTV via rail 116b interface each other. To alleviate issues with overlay error, the feedthrough via 114 may be formed as part of a self-aligned process using a cut-metal-gate feature as described with respect to FIGS. 10-17.

FIG. 1C illustrates a cross-sectional view of the semiconductor structure 100 cut along an active region 106 along the x direction. The active region 106 includes a channel region 106a between S/D regions 106b. The S/D regions 106b include epitaxial features doped with n-type or p-type dopants for n-type transistors or p-type transistors, respectively. A metal gate structure 108 is disposed over the channel region 106a. The metal gate structure 108 may wrap around channel layers in the channel region 106a for a GAA device (not shown). The dielectric structure 150 having the first ILD layer 130, the etch stop layer 111, and the second ILD layer 140 is disposed over the active region 106, and S/D contacts 112 penetrates through the second ILD layer 140, the etch stop layer 111, and the first ILD layer 130 to land on the S/D regions 106b. The etch stop layer 111 may land on a top surface of the metal gate structure 108, and a metal gate contact 110 may penetrate through the second ILD layer 140 and the etch stop layer 111 to land on the metal gate structure 108. As shown, top surfaces of the S/D contacts 112, the dielectric structure 150, and the metal gate contact 110 are substantially coplanar, and bottom surfaces of the S/D contacts 112 are below a bottom surface of the metal gate contact 110. Although not shown, a gate via may penetrate through the third ILD layer 160 and the etch stop layer 113 to land on the metal gate contact 110. In another embodiment, there is no metal gate contact 110, and a gate via may directly penetrate through the third ILD layer 160, the etch stop layer 113, and the second ILD layer 140 to land on the metal gate structure 108. In this embodiment, the top surface of the gate via is above the top surface of the S/D contacts 112.

Now referring to FIG. 1D, a frontside via 116, such as an S/D via rail 116a may penetrate through the third ILD layer 160 and the etch stop layer 113 to land on an extended portion of the S/D contacts 112. FIG. 1D illustrates a cross-sectional view of the semiconductor structure 100 cut along an S/D via rail 116a along the x direction. As shown, the extended portion of the S/D contact 112 have side and bottom surfaces directly contacting and surrounded by the dielectric structure 150. Also as shown, in this view, the metal gate structure 108 may vertically extend deeper into the first ILD layer 130, such as to a shallow trench isolation structure (not shown) as part of or below the first ILD layer 130 or directly landing on the hard mask layer 117 as shown.

Now referring to FIGS. 1B-ID collectively, the bottom surfaces of the S/D via rail 116a and the FTV via rail 116b are substantially coplanar. The S/D contacts 112 partially penetrates through the dielectric structure 150 (i.e., completely through the second ILD layer 140, the etch stop layer 111, and partially through the first ILD layer 130) to land on S/D regions 106b. The feedthrough via 114 completely penetrates through the dielectric structure 150 to land on the backside metal 118. Due to the partial penetration of the feedthrough via 114 into the FTV via rail 116b, a top surface of the feedthrough via 114 may be above the top surface of the S/D contacts 112.

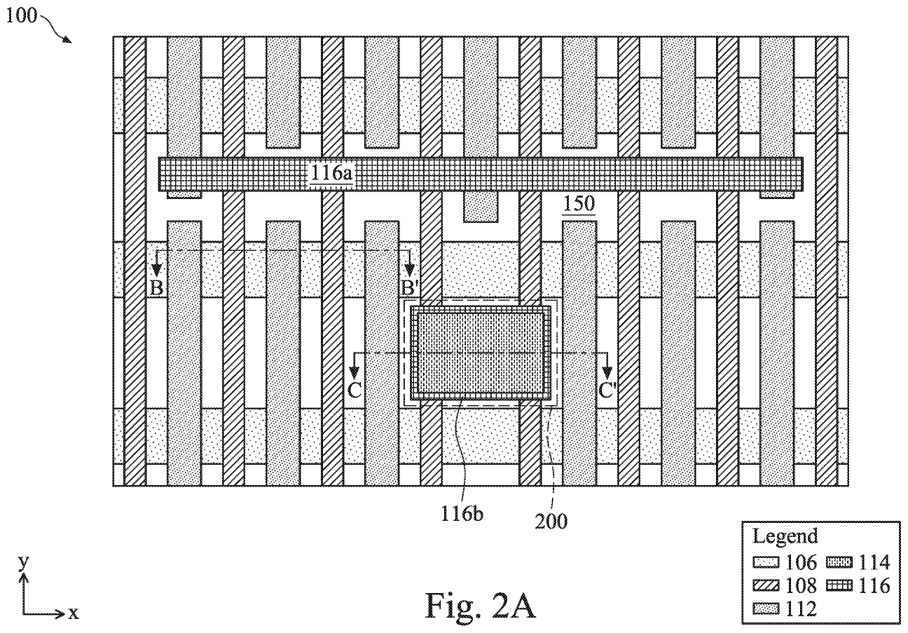

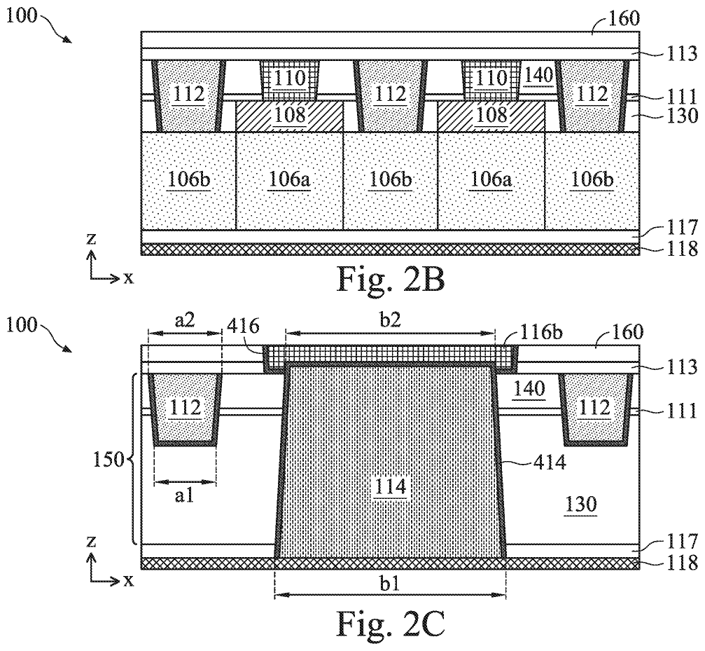

FIG. 2A illustrates a top view of a semiconductor structure 100 having a feedthrough circuit area 200 surrounded by transistor circuit areas, according to another embodiment of the present disclosure. FIG. 2A is similar to FIG. 1A and the similar features will not be described again for the sake of brevity. The difference here is that the feedthrough circuit area 200 having the feedthrough via 114 and FTV via rail 116b have a smaller dimension along the x direction between two S/D contacts 112, and portions of the active regions 106 that sandwich the feedthrough circuit area 200 do not have recessed width in the y direction. In other words, the feedthrough circuit area 200 is more compact and more seamlessly integrated with the surrounding transistor regions. As shown, the feedthrough circuit area 200 merely replaces a portion of the transistor circuit areas that otherwise would have had an S/D contact 112.

FIGS. 2B-2C illustrate cross-sectional views of an embodiment semiconductor structure 100 cut along the lines B-B′ and C-C′ in FIG. 2A, according to an embodiment of the present disclosure. Although the lines B-B′ and C-C′ are cut along different portions of the semiconductor structure 100, the lines B-B′ and C-C′ have the same length along the x direction for easier side-by-side comparison between FIG. 2B and FIG. 2C. FIG. 2B is similar to FIG. 1B except that FIG. 2B extends longer in the x direction to show an extra S/D contact 112 over another S/D region 106b. FIG. 2C is similar to FIG. 2B except that instead of having an S/D contact 112 between two other S/D contacts 112, a feedthrough via 114 is between two other S/D contacts 112 (or specifically the extended portions of the S/D contacts 112 that do not land on the S/D regions 106b). In this cross-section, the feedthrough via 114 and the FTV via rail 116b include the glue layers 414 and 416 and show similar configurations as those shown in the cross-section in FIG. 1B (e.g., feedthrough via 114 penetrates through the dielectric structure 150 to connect between the FTV via rail 116b and the backside metal 118). Although not shown, the feedthrough via 114 may also cut through portions of the metal gate structures 108 that span across the feedthrough circuit area 200.

Still referring to FIG. 2C, the S/D contacts 112 have a wider top width a2 that narrows down to a narrower bottom width a1. The feedthrough via 114 has a narrower top width b2 that widens down to a wider bottom width b1. In the present embodiment, since the feedthrough via 114 is not limited to the patterning limitations of the S/D contacts 112, the feedthrough via 114 may be formed wider between the S/D contacts 112 along the x direction. In the present embodiment, the top width b2 of the feedthrough via 114 is wider than the bottom width a1 of the S/D contacts 112. This way, there is improved surface contact and lowered resistance for the feedthrough via 114 to maximize surface interface with the FTV via rail 116b. In an embodiment, the ratio of the width b2 to the width a1 is at least 1.25 to achieve improved resistance and prevent overlay error. In an embodiment, the ratio of the width b1 to the width b2 is greater than 1.1. In an embodiment, the width a1 ranges between about 3 nm to about 50 nm, and the width b2 is greater than the width a1 by about 20 nm to about 60 nm. In an embodiment, the width b1 ranges between about 25 nm to about 120 nm, and the width b1 is greater than the width b2 by about 15 to about 25 nm.

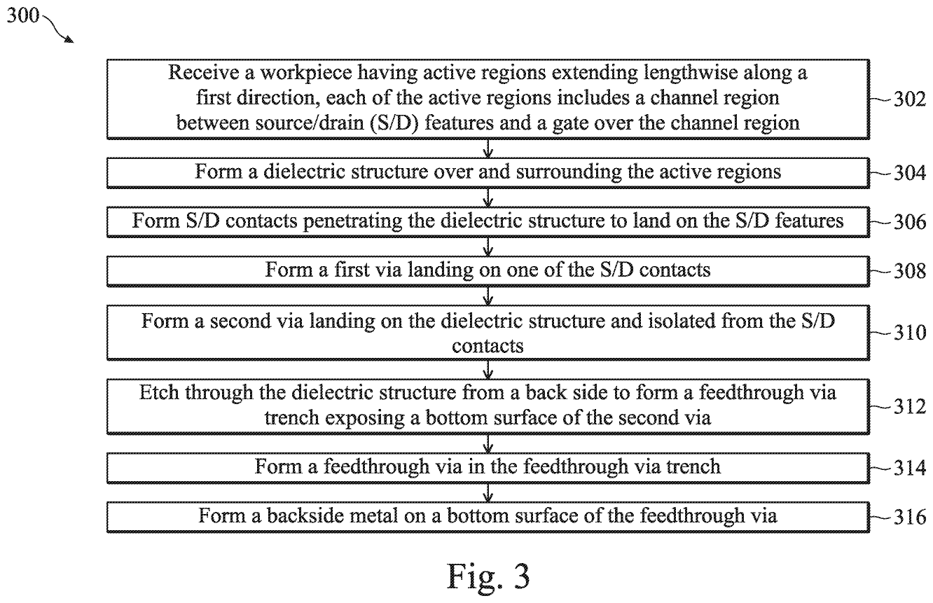

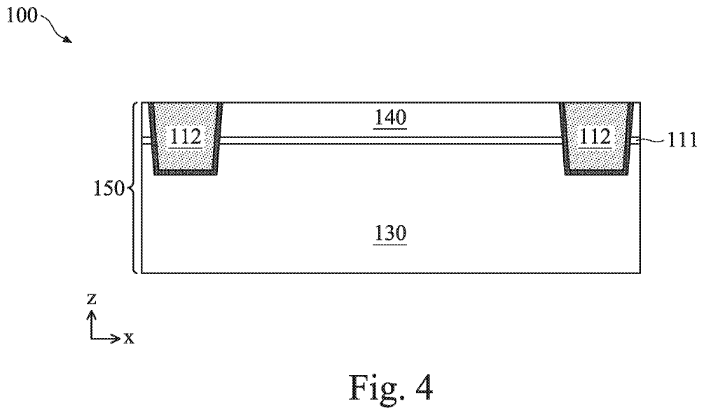

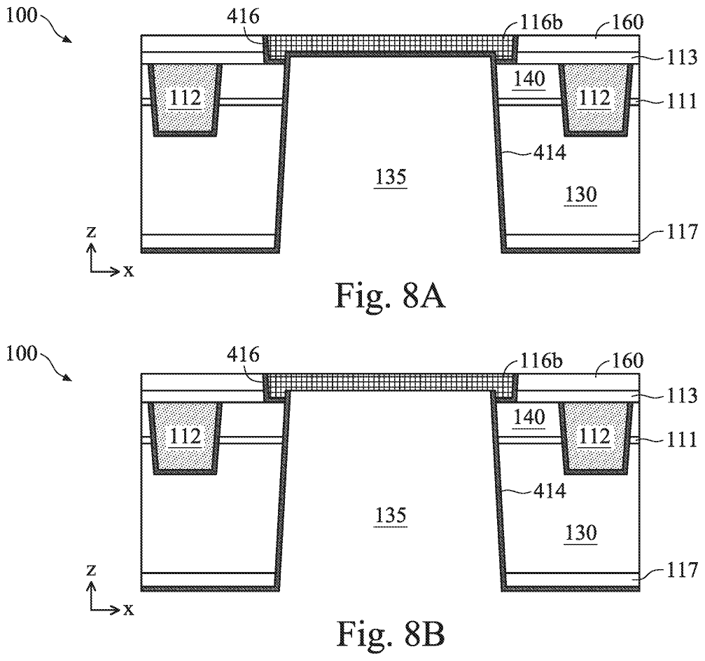

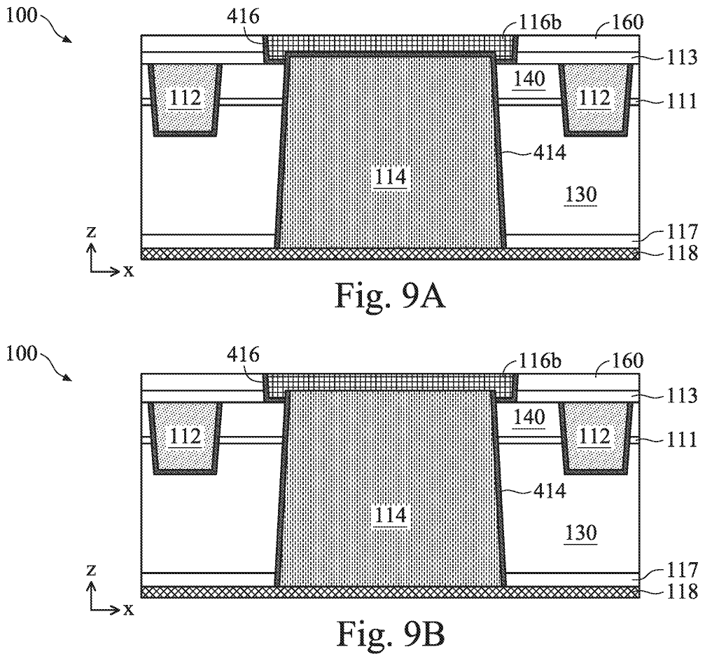

FIG. 3 illustrates a flow chart of a method 300 to form a semiconductor structure 100 having a feedthrough via 114 adjacent to device level metal contacts (e.g., S/D contacts 112), according to an embodiment of the present disclosure. FIG. 4-9 (including sub-figures FIGS. 8A-8B, and 9A-9B), illustrate the formation of a semiconductor structure 100 at intermediate stages of fabrication, processed in accordance with the method 300 of FIG. 3. Method 300 is described below with reference to FIGS. 4-9, which depicts intermediate stages of forming the semiconductor structure 100 as shown in FIGS. 1B-1D and/or 2B-2C. The intermediate stages are described with respect to cross-sectional views along the line C-C′ in FIG. 2A. Additional operations can be provided before, during, and after the method 300, and some of the operations described can be moved, replaced, or eliminated for additional embodiments of method 300. Note that the features that have been described with respect to FIGS. 1A-ID and 2A-2C may equally describe the similarly labeled features in FIGS. 4-9.

The method 300 at operation 302 receives a semiconductor workpiece having active regions 106 extending lengthwise along a first direction, each of the active regions 106 includes a channel region 106a between source/drain (S/D) features in the S/D regions 106b and a gate (e.g., metal gate structure 108) over the channel region 106a (see FIG. 1C). The active regions 106 may be formed over a substrate (not shown). The substrate may include silicon (Si), or other semiconductor materials such as germanium (Ge), silicon carbide (SiC), silicon germanium (SiGe), or diamond. The active regions 106 may be surrounded by an isolation structure such as a shallow trench isolation (STI) structure (not explicitly shown but may be a lower portion of or below the first ILD layer 130). The isolation structure may include silicon oxide, silicon oxynitride, fluorine-doped silicate glass (FSG), a low-k dielectric, combinations thereof, and/or other suitable materials.

Referring now to FIG. 4, the method 300 at operation 304 forms a dielectric structure 150 over and surrounding the active regions 106 (see also FIG. 1C). Operation 304 may include forming a first ILD layer 130 over and surrounding the active regions 106, forming an etch stop layer 111 over the first ILD layer 130, and forming a second ILD layer 140 over the etch stop layer 111. The dielectric structure 150 may be formed by any suitable deposition process such as chemical vapor deposition. The etch stop layer 111 may be formed over a top surface of a gate (e.g., metal gate structure 108).

Still referring to FIG. 4, the method 300 at operation 306 forms S/D contacts 112 penetrating the dielectric structure 150. As shown in FIG. 4, the S/D contacts 112 penetrates through the second ILD layer 140 and the etch stop layer 111 and partially penetrates the first ILD layer 130. The S/D contacts 112 partially penetrates the ILD layer 130 to land on the S/D features in the S/D regions 106b (shown in FIG. 1C). Other portions of the S/D contacts 112 land on unpenetrated portions of the first ILD layer 130 (shown in FIG. 4). The S/D contacts 112 may be formed by a patterning process to form S/D trenches exposing the S/D regions 106b and filling the trenches with metal features such as a glue layer and a metal fill. The patterning process may include depositing photoresists and/or hard masks over the dielectric structure 150, patterning the photoresists and/or hard masks through a lithography process to define portions of the dielectric structure 150 to be etched, and etching the dielectric structure 150 using the patterned photoresist and/or hard masks as an etch mask to form the S/D trenches. After the patterning process, S/D trenches are formed, and metal features are deposited in the S/D trenches to form the S/D contacts 112. Thereafter, a CMP process may be performed to planarize top surfaces of the S/D contacts 112 and the dielectric structure 150. The resulting structure is shown in FIG. 4.

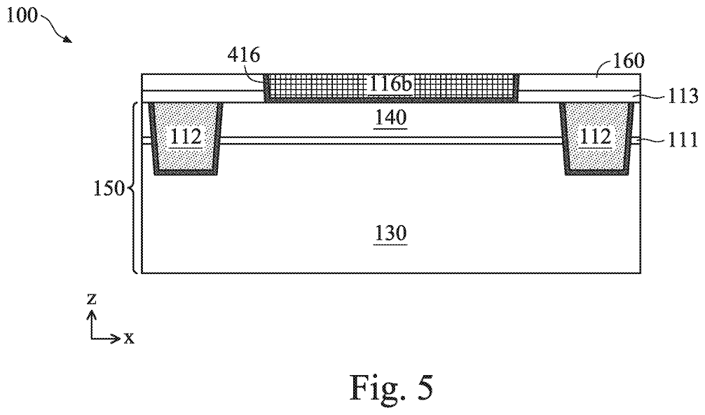

Referring now to FIG. 5, the method 300 performs operations 308 and 310. The method at operation 308 forms a first via (e.g., S/D via rail 116a) landing on one of the S/D contacts 112 (see FIG. 1D). The method 300 at operation 310 forms a second via (e.g., FTV via rail 116b) landing on the dielectric structure 150 and isolated from the S/D contacts 112. The first and second vias are separated from each other by the etch stop layer 113 and the third ILD layer 160. Although the present disclosure describes forming the first via and the second via (e.g., S/D via rail 116a and FTV via rail 116b) in two operation steps, they may be formed in a same operation step. The operations 308 and 310 may include depositing an etch stop layer 113 over top surfaces of the S/D contacts 112 and the second ILD layer 140, depositing a third ILD layer 160 over the etch stop layer 113, performing a patterning process to form respective first and second via trenches in the third ILD layer 160 and the etch stop layer 113, and filling the trenches with metal features such as a glue layer and a metal fill, thereby forming respective first and second vias (e.g., S/D via rail 116a and FTV via rail 116b) in the first and second via trenches. Thereafter, a CMP process may be performed to planarize top surfaces of the third ILD layer 160 and the first and second vias (e.g., S/D via rail 116a and FTV via rail 116b). Note that the first and second vias (e.g., S/D via rail 116a and FTV via rail 116b) are disposed in a same material layer (substantially coplanar top and bottom surfaces) over the dielectric structure 150.

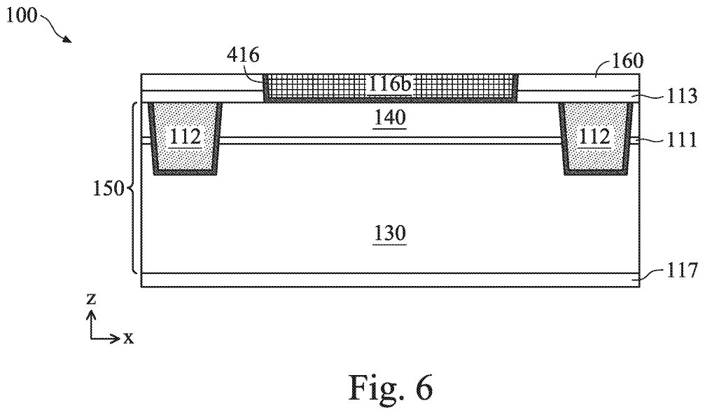

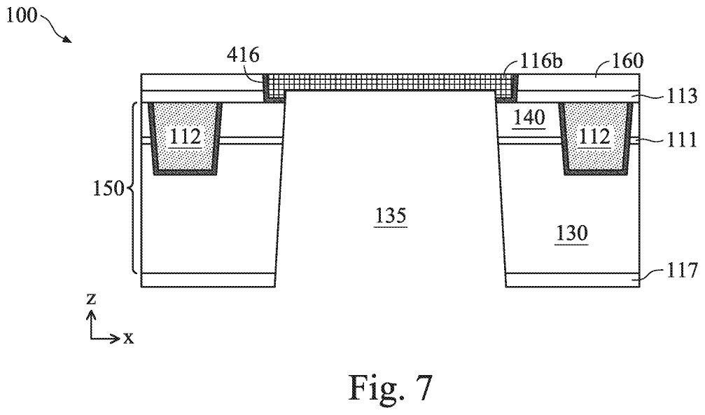

Referring now to FIGS. 6-7, the method 300 at operation 312 etches through the dielectric structure 150 from a back side to form a feedthrough via trench 135 exposing a bottom surface of the second via (e.g., FTV via rail 116b). The operation 312 may be performed after a frontside metal interconnect structure (not shown) is formed over the dielectric structure 150. In an embodiment, the first and second vias may be a part of the frontside metal interconnect structure, in which additional metal features such as metal lines and interconnect vias between the metal lines are formed over the first and second vias. After forming the frontside metal interconnect structure, a carrier wafer may be attached to the workpiece on the frontside. The carrier wafer provides structural support in preparation for backside processing. Referring to FIG. 6, the method 300 at operation 312 includes first thinning down the substrate from which the active regions 106 are formed thereon. The substrate is thinned down from a back side of the workpiece and may be partially or fully removed. Note that the thinning down process may be performed before or after the semiconductor structure 100 is flipped in the z direction for further backside processing. In the embodiment shown, the substrate is fully removed to expose a bottom surface of the first ILD layer 130. The thinning down process may involve etching away bottom portions of an isolation structure (e.g., STI), which surrounds the active regions 106. Then, the operation 312 may include depositing a hard mask layer 117 over the exposed bottom surface of the first ILD layer 130. Referring now to FIG. 7, the method 300 at operation 312 forms a feedthrough via trench 135 by a patterning process. The patterning process may include depositing photoresists and/or hard masks on a bottom surface of the hard mask layer 117 (note that the workpiece may be flipped), patterning the photoresists and/or hard masks through a lithography process to define an opening of the hard mask layer 117 to be etched, and etching through the opening using the patterned photoresist and/or hard masks as an etch mask to form the feedthrough via trench 135. Etching through the opening includes completely etching through the hard mask layer 117, the first ILD layer 130, the etch stop layer 111, and the second ILD layer 140 to expose the FTV via rail 116b. In the embodiment shown, there is an over-etch to penetrate through a bottom portion of the glue layer 416. Note that since the FTV via rail 116b is formed from the backside, the profile of the FTV via rail 116b is narrower towards the top.

Referring now to FIGS. 8-9 (including FIGS. 8A-8B and 9A-9B), the method 300 at operation 314 forms a feedthrough via 114 in the feedthrough via trench 135. Referring first to FIG. 8A, operation 314 includes conformally depositing a glue layer 414 in the trench 135 and over a bottom surface of the hard mask layer 117. As shown in FIG. 8A, a top horizontal portion of the glue layer 414 is in direct contact with a bottom horizontal portion of the FTV via rail 116b. In a further embodiment, as shown in FIG. 8B, the top horizontal portion is then removed to reduce resistivity caused by glue layer interfaces. Note that previously by forming the feedthrough via trench 135 to penetrate through the glue layer 416, resistivity is already reduced by removing a layer of glue layer interface, and now by removing the top horizontal portion of the glue layer 414, resistivity is further reduced by removing a second layer of glue layer interface. The top horizontal portion of the glue layer 414 may be removed through selective plasma etching. Referring now to FIGS. 9A-9B, a via metal fill layer is deposited in the feedthrough via trench 135 and over the glue layer 414. In a first embodiment, as shown in FIG. 9A, the glue layer 414 is disposed on side and top surfaces of the via fill layer, and the via fill layer is separated from the FTV via rail 116b (or metal fill portion thereof) by a top horizontal portion of the glue layer 416. In a second embodiment, as shown in FIG. 9B, the glue layer 414 is disposed on side surfaces of the via fill layer but not on a top surface of the via fill layer, and the top surface of the via fill layer directly contacts the FTV via rail 116b (or metal fill portion thereof). Referring to FIGS. 9A and 9B, the method 300 at operation 316 then forms a backside metal 118 on a bottom surface of the feedthrough via 114 by any suitable deposition process.

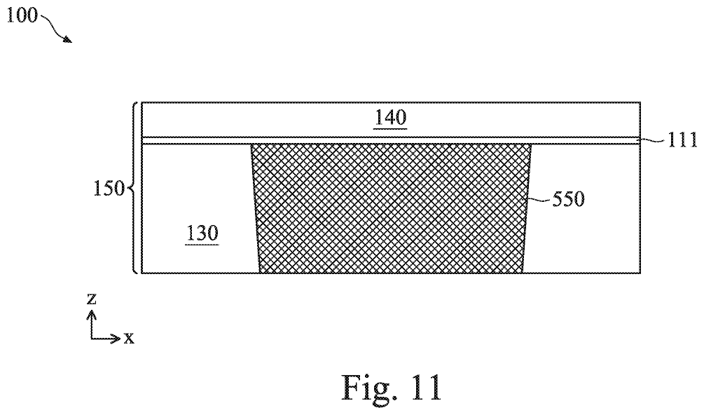

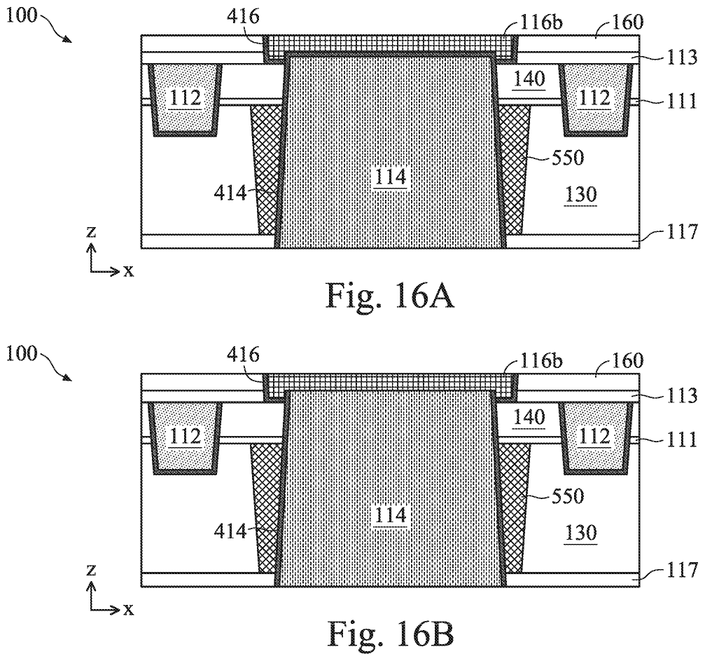

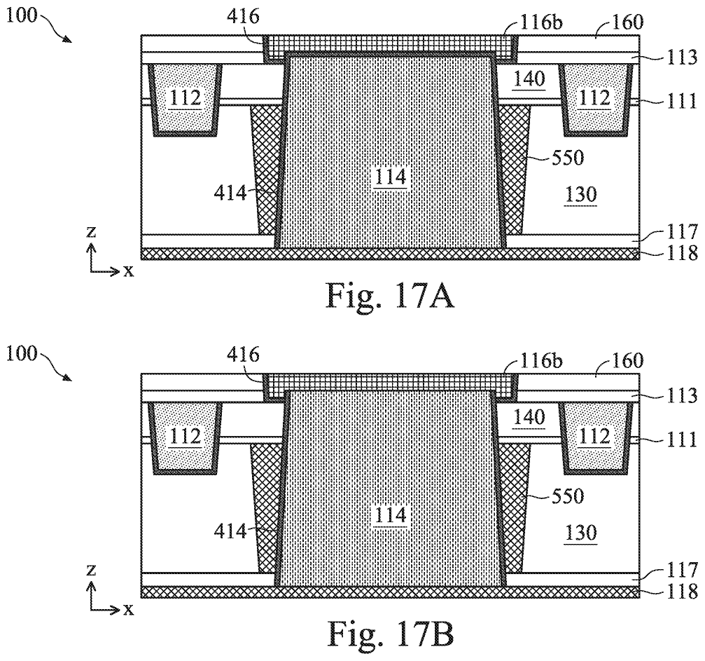

FIG. 10 illustrates a flow chart of a method 500 to form a semiconductor structure 100 having a feedthrough via 114 adjacent to device level metal contacts (e.g., S/D contacts 112), according to another embodiment of the present disclosure. Method 500 is similar to method 300, and some of the similar features will not be described again for the sake of brevity. The difference is that the method 500 incorporates a cut-metal-gate feature 550. The cut-metal-gate feature 550 creates a safe zone for etching the feedthrough via trench 135, thereby creating self-alignment and reducing overlay errors when forming the feedthrough via 114 onto the back side of the FTV via rail 116b. Method 500 is described below with reference to FIGS. 11-17 (including sub-figures FIGS. 16A-16B, and 17A-17B), which depicts intermediate stages of forming a semiconductor structure 100 similar to those shown in FIGS. 1B-1D and/or 2B-2C, but now incorporating a cut-metal-gate feature 550. The intermediate stages are described with respect to cross-sectional views along the line C-C′ in FIG. 2A. Additional operations can be provided before, during, and after the method 500, and some of the operations described can be moved, replaced, or eliminated for additional embodiments of method 500. Note that the features that have been described with respect to FIGS. 1A-ID and 2A-2C may equally describe the similarly labeled features in FIGS. 11-17.

The method 500 at operation 502 receives a workpiece having active regions 106 extending lengthwise along a first direction, each of the active regions 106 includes a channel region 106a between S/D features in the S/D regions 106b and a gate (e.g., metal gate structure 108) over the channel region 106a (see FIG. 1C). Operation 502 is similar to operation 302 and will not be described again for the sake of brevity.

Referring now to FIG. 11, the method 500 at operation 504 forms a dielectric structure 150 over and surrounding the active regions 106, the dielectric structure 150 includes a first interlayer dielectric layer (ILD) 130 surrounding a cut-metal-gate (CMG) feature 550, an etch stop layer 111 over the first ILD layer 130 and the CMG feature 550, and a second ILD layer 140 over the etch stop layer 111. Operation 504 may include forming the first ILD layer 130 over and surrounding the active regions 106, forming the CMG feature 550 in the first ILD layer 130, forming the etch stop layer 111 over the first ILD layer 130 and the CMG feature 550, and forming the second ILD layer 140 over the etch stop layer 111. The CMG feature 550 is formed by first forming a CMG trench in the first ILD layer 130 by a patterning process. Forming the CMG trench may involve etching away one or more portions of the metal gate structure 108 that extend into the feedthrough circuit area 200 (see FIGS. 1A and 2A). The patterning process may include depositing photoresists and/or hard masks on a top surface of the first ILD layer 130 (not shown), patterning the photoresists and/or hard masks through a lithography process to define an opening of the hard mask layer 117 to be etched, and etching through the opening using the patterned photoresist and/or hard masks as an etch mask to form the CMG trench. Etching through the opening may include completely etching through the first ILD layer 130 and extended portions of the metal gate structure 108. Then, a dielectric material is deposited in the CMG trench to form the CMG feature 550. The CMG feature 550 includes different dielectric materials from the first ILD layer 130 for etchant selectivity and for a self-alignment process when later forming the feedthrough via 114. For example, the first ILD layer 130 includes an oxide-based dielectric (e.g., silicon oxide), and the CMG feature includes a nitride-based dielectric (e.g., silicon nitride, silicon oxynitride, silicon carbonitride, silicon carbon oxynitride, or combinations thereof). After forming the CMG feature 550, a CMP process may be performed to planarize top surfaces of the first ILD layer 130 and the CMG feature 550. Thereafter, the etch stop layer 111 and the second ILD layer 140 is deposited to finish forming the dielectric structure 150.

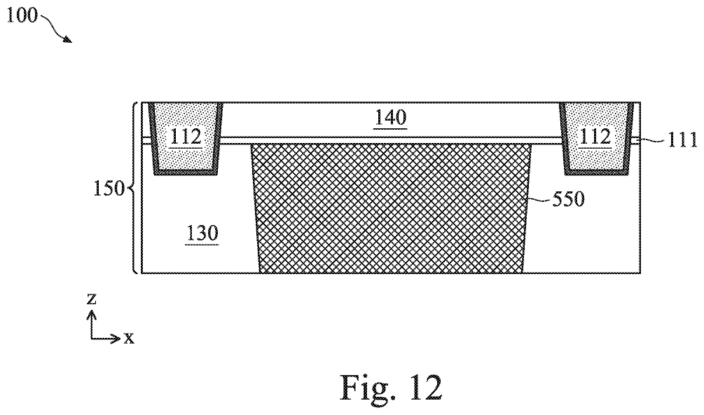

Referring to FIG. 12, the method 500 at operation 506 form S/D contacts 112 penetrating the dielectric structure 150. The S/D contacts 112 completely penetrates through the second ILD layer 140 and the etch stop layer 111 and partially penetrates the ILD layer 130 to land on the S/D features in the S/D regions 106b (shown in FIG. 1C). Other portions of the S/D contacts 112 land on unpenetrated portions of the first ILD layer 130 (shown in FIG. 12). As shown, the S/D contacts 112 are formed to have top surfaces above the top surface of the CMG feature 550. Operation 506 is similar to operation 306 and the similar features will not be described again for the sake of brevity.

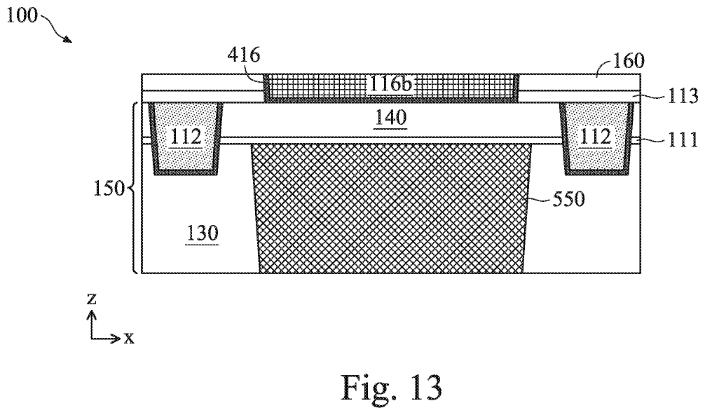

Referring now to FIG. 13, the method 500 at operation 508 forms a first via (e.g., S/D via rail 116a) landing on one of the S/D contacts 112 (see FIG. 1D), and the method 500 at operation 510 forms a second via (e.g., FTV via rail 116b) landing on the dielectric structure 150 and isolated from the S/D contacts 112. Operations 508 and 510 are similar to operations 308 and 310 and the similar features will not be described again for the sake of brevity.

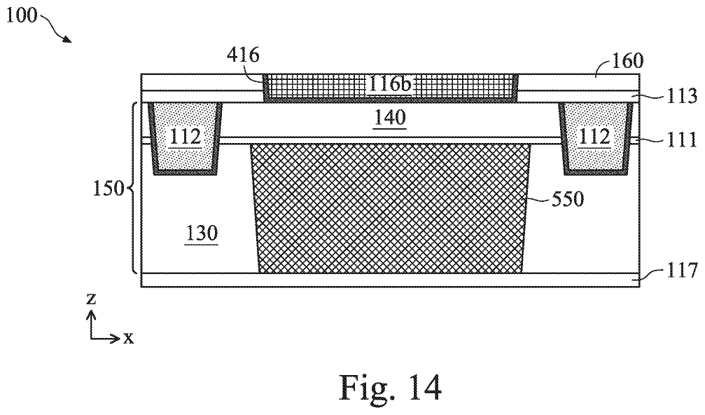

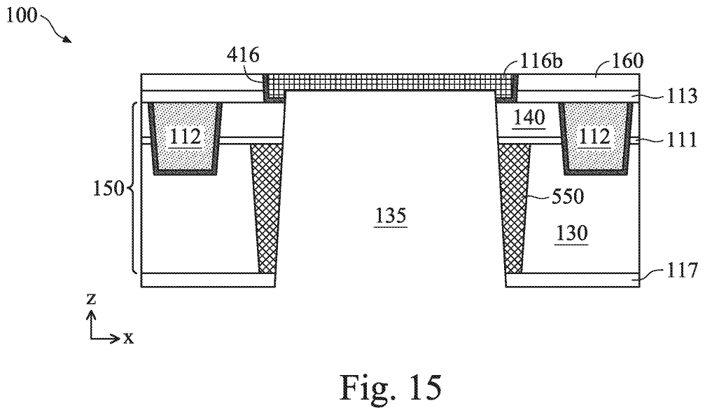

Referring now to FIGS. 14-15, the method 500 at operation 512 etches through the dielectric structure 150 by etching through the CMG feature 550, the etch stop layer 111, and the second ILD layer 140 from a back side to form a feedthrough via trench 135 exposing a bottom surface of the second via (e.g., FTV via rail 116b). Operation 512 is similar to operation 312, and the similar features will not be described again for the sake of brevity. However, due to the presence of the CMG feature 550, the process to form the feedthrough via trench 135 is improved. The CMG feature 550 provides etching selectivity to form a safe zone such that the etching process etches through the CMG feature 550 without risks of etching other unintended areas. Once the CMG feature 550 is etched through, there is self-alignment in etching through the remaining etch stop layer 111 and second ILD layer 140 to expose the FTV via rail 116b. If there is overlay shift, the different compositions and the etching selectivity will constrain the etching to be within the CMG feature 550. In this way, risks of overlay errors is reduced despite the top narrowing profile of the feedthrough via trench 135.

Referring now to FIG. 16 (including FIGS. 16A-16B), the method 500 at operation 514 forms a feedthrough via 114 in the feedthrough via trench 135. Operation 514 is similar to operation 314 and the similar features will not be described again for the sake of brevity. Note that the feedthrough via 114 may be separated from the first ILD layer 130 by remaining unetched portions of the CMG feature 550. Referring now to FIG. 17 (including FIGS. 17A-17B), the method 500 at operation 516 then forms a backside metal 118 on a bottom surface of the feedthrough via 114 by any suitable deposition process.

Although not limiting, the present disclosure offers advantages for semiconductor structures having a feedthrough via. One example advantage is that the feedthrough via completely penetrates through a dielectric structure to connect between a frontside via and a backside metal. This way, feedthrough resistance is reduced due to less glue layer interfaces. Another example advantage is performing over-etching when forming the feedthrough via to remove a glue layer interface. Another example advantage is performing a plasma etch to remove a further glue layer interface when forming the feedthrough via. Another example advantage is incorporating a cut-metal-gate dielectric feature for self-alignment between the feedthrough via and a feedthrough via rail.

One aspect of the present disclosure pertains to a semiconductor structure. The semiconductor structure includes a first circuit area having: an active region extending lengthwise along a first direction, the active region includes a channel region between source/drain (S/D) features and a gate over the channel region, a dielectric structure over and surrounding the active region, a metal contact penetrating through a top surface of the dielectric structure to land on one of the S/D features, and a first via landing on the metal contact. The semiconductor structure includes a second circuit area having: the dielectric structure, a feedthrough via penetrating through the top surface of the dielectric structure and a bottom surface of the dielectric structure, and a second via landing on the feedthrough via. The first via and the second via have substantially coplanar bottom surfaces.

In an embodiment, the feedthrough via partially penetrates through a bottom surface of the second via. In a further embodiment, the second via includes a glue layer and a via fill layer, the glue layer is disposed on side and bottom surfaces of the via fill layer, and the feedthrough via completely penetrates through a bottom portion of the glue layer disposed directly on the via fill layer.

In an embodiment, the feedthrough via continuously and uniformly spans from the bottom surface of the dielectric structure to at least the top surface of the dielectric structure.

In an embodiment, the feedthrough via includes a glue layer and a via fill layer, the glue layer is disposed on side and top surfaces of the via fill layer, and the via fill layer is separated from the second via by the glue layer.

In an embodiment, the feedthrough via includes a glue layer and a via fill layer, the glue layer is disposed on side surfaces of the via fill layer but not on a top surface of the via fill layer, and the top surface of the via fill layer directly contacts the second via.

In an embodiment, bottom and side surfaces of the metal contact is embedded in the dielectric structure, and the bottom surface of the metal contact is below a top surface of the feedthrough via.

In an embodiment, the dielectric structure embeds a bottom etch stop layer. The bottom etch stop layer lands on a top surface of the gate. The metal contact and the feedthrough via both penetrate through the bottom etch stop layer. In a further embodiment, the semiconductor structure further includes a top etch stop layer, where the first and second vias penetrate through the top etch stop layer to land on the metal contact and the feedthrough via, respectively.

In an embodiment, where along the first direction, a top width of the feedthrough via is greater than a bottom width of the metal contact.

Another aspect of the present disclosure pertains to a semiconductor structure. The semiconductor structure includes a first circuit area having: an active region extending lengthwise along a first direction, the active region includes a channel region between source/drain (S/D) features and a gate over the channel region, a dielectric structure over and surrounding the active region, a metal contact having a first portion penetrating a first distance into the dielectric structure to land on one of the S/D features, and a first via landing on the metal contact, and a second circuit area having: a second portion of the metal contact having bottom and side surfaces directly contacting the dielectric structure; a feedthrough via adjacent to the second portion of the metal contact and penetrating a second distance into the dielectric structure; and a second via landing on the feedthrough via. The second distance is greater than the first distance.

In an embodiment, the semiconductor structure further includes a backside metal below a bottom surface of the dielectric structure, and the feedthrough via lands on a top surface of the backside metal.

In an embodiment, the first circuit area further includes: a second channel region of the active region between second source/drain (S/D) features and a second gate over the second channel region, and a second metal contact having a first portion penetrating the first distance into the dielectric structure to land on one of the second S/D features. The second circuit area further includes a second portion of the second metal contact landing on another horizontal surface of the dielectric structure, and the feedthrough via is laterally disposed between the first and second metal contacts along the first direction.

In an embodiment, the feedthrough via has a top width along the first direction, a bottom width along the first direction, and the bottom width is greater than the top width. In a further embodiment, the metal contact has a bottom width, and the top width of the feedthrough via is greater than the bottom width of the metal contact.

In an embodiment, the dielectric structure embeds a bottom etch stop layer, the bottom etch stop layer lands on a top surface of the gate, and the metal contact and the feedthrough via both penetrate through the bottom etch stop layer.

In an embodiment, the dielectric structure includes an interlayer dielectric (ILD) layer surrounding a cut-metal-gate (CMG) feature, the CMG feature separates the feedthrough via from the ILD layer and the feedthrough via penetrates through the CMG feature, and the ILD layer and the CMG feature include different dielectric materials.

Another aspect of the present disclosure pertains to a method of forming a semiconductor structure. The method includes receiving a workpiece having active regions extending lengthwise along a first direction, each of the active regions includes a channel region between source/drain (S/D) features and a gate over the channel region; forming a dielectric structure over and surrounding the active region; forming metal contacts penetrating the dielectric structure to land on the S/D features; forming a first via landing on one of the metal contacts; forming a second via landing on the dielectric structure and isolated from the metal contacts; etching through the dielectric structure from a back side to form a feedthrough via trench exposing a bottom surface of the second via; and forming a feedthrough via in the feedthrough via trench.

In an embodiment, the dielectric structure includes a first interlayer dielectric (ILD) layer, and the method further includes: before forming the metal contacts, forming a cut-metal-gate (CMG) feature in the first ILD layer and replacing one or more gates between two of the S/D features along the first direction. The etching through of the first ILD layer includes etching through the CMG feature to form the feedthrough via trench.

In an embodiment, the forming of the feedthrough via includes: conformally depositing a glue layer in the feedthrough via trench; and depositing a via fill layer over the glue layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
a first circuit area having:
an active region extending lengthwise along a first direction, the active region includes a channel region between source/drain (S/D) features and a gate over the channel region,
a dielectric structure over and surrounding the active region,
a metal contact penetrating through a top surface of the dielectric structure to land on one of the S/D features, and
a first via landing on the metal contact; and
a second circuit area having:
the dielectric structure,
a feedthrough via penetrating through the top surface of the dielectric structure and a bottom surface of the dielectric structure, and
a second via landing on the feedthrough via,
wherein the first via and the second via have substantially coplanar bottom surfaces.

2. The semiconductor structure of claim 1, wherein the feedthrough via partially penetrates through a bottom surface of the second via.

3. The semiconductor structure of claim 2,
wherein the second via includes a glue layer and a via fill layer, the glue layer is disposed on side and bottom surfaces of the via fill layer,
wherein the feedthrough via completely penetrates through a bottom portion of the glue layer disposed directly on the via fill layer.

4. The semiconductor structure of claim 1, wherein the feedthrough via continuously and uniformly spans from the bottom surface of the dielectric structure to at least the top surface of the dielectric structure.

5. The semiconductor structure of claim 1,
wherein the feedthrough via includes a glue layer and a via fill layer,
wherein the glue layer is disposed on side and top surfaces of the via fill layer, and the via fill layer is separated from the second via by the glue layer.

6. The semiconductor structure of claim 1,
wherein the feedthrough via includes a glue layer and a via fill layer,
wherein the glue layer is disposed on side surfaces of the via fill layer but not on a top surface of the via fill layer, and the top surface of the via fill layer directly contacts the second via.

7. The semiconductor structure of claim 1, wherein bottom and side surfaces of the metal contact is embedded in the dielectric structure, and the bottom surface of the metal contact is below a top surface of the feedthrough via.

8. The semiconductor structure of claim 1,
wherein the dielectric structure embeds a bottom etch stop layer, wherein the bottom etch stop layer lands on a top surface of the gate,
wherein the metal contact and the feedthrough via both penetrate through the bottom etch stop layer.

9. The semiconductor structure of claim 8, further comprising:
a top etch stop layer, wherein the first and second vias penetrate through the top etch stop layer to land on the metal contact and the feedthrough via, respectively.

10. The semiconductor structure of claim 1, wherein along the first direction, a top width of the feedthrough via is greater than a bottom width of the metal contact.

11. A semiconductor structure, comprising:
a first circuit area having:
an active region extending lengthwise along a first direction, the active region includes a channel region between source/drain (S/D) features and a gate over the channel region,
a dielectric structure over and surrounding the active region,
a metal contact having a first portion penetrating a first distance into the dielectric structure to land on one of the S/D features, and
a first via landing on the metal contact, and
a second circuit area having:
a second portion of the metal contact having bottom and side surfaces directly contacting the dielectric structure;
a feedthrough via adjacent to the second portion of the metal contact and penetrating a second distance into the dielectric structure; and
a second via landing on the feedthrough via,
wherein the second distance is greater than the first distance.

12. The semiconductor structure of claim 11, further comprising:
a backside metal below a bottom surface of the dielectric structure, and the feedthrough via lands on a top surface of the backside metal.

13. The semiconductor structure of claim 11, wherein the first circuit area further comprises:
a second channel region of the active region between second source/drain (S/D) features and a second gate over the second channel region, and
a second metal contact having a first portion penetrating the first distance into the dielectric structure to land on one of the second S/D features,
wherein the second circuit area further includes a second portion of the second metal contact landing on another horizontal surface of the dielectric structure, and the feedthrough via is laterally disposed between the first and second metal contacts along the first direction.

14. The semiconductor structure of claim 11, wherein the feedthrough via has a top width along the first direction, a bottom width along the first direction, and the bottom width is greater than the top width.

15. The semiconductor structure of claim 14,
wherein the metal contact has a bottom width,
and wherein the top width of the feedthrough via is greater than the bottom width of the metal contact.

16. The semiconductor structure of claim 11,
wherein the dielectric structure embeds a bottom etch stop layer, wherein the bottom etch stop layer lands on a top surface of the gate,
wherein the metal contact and the feedthrough via both penetrate through the bottom etch stop layer.

17. The semiconductor structure of claim 11,
wherein the dielectric structure includes an interlayer dielectric (ILD) layer surrounding a cut-metal-gate (CMG) feature,
wherein the CMG feature separates the feedthrough via from the ILD layer and the feedthrough via penetrates through the CMG feature,
wherein the ILD layer and the CMG feature include different dielectric materials.

18. A method of forming a semiconductor structure, comprising:
receiving a workpiece having active regions extending lengthwise along a first direction, each of the active regions includes a channel region between source/drain (S/D) features and a gate over the channel region;
forming a dielectric structure over and surrounding the active region;
forming metal contacts penetrating the dielectric structure to land on the S/D features;
forming a first via landing on one of the metal contacts;
forming a second via landing on the dielectric structure and isolated from the metal contacts;
etching through the dielectric structure from a back side to form a feedthrough via trench exposing a bottom surface of the second via; and
forming a feedthrough via in the feedthrough via trench.

19. The method of claim 18, wherein the dielectric structure includes a first interlayer dielectric (ILD) layer, further comprising:
before forming the metal contacts, forming a cut-metal-gate (CMG) feature in the first ILD layer and replacing one or more gates between two of the S/D features along the first direction,
wherein the etching through of the first ILD layer includes etching through the CMG feature to form the feedthrough via trench.

20. The method of claim 18, wherein the forming of the feedthrough via includes:
conformally depositing a glue layer in the feedthrough via trench; and
depositing a via fill layer over the glue layer.
